(19) United States
(12) Patent Application Publication
(10) Pub. No.: US 2024/0389432 A1
(43) Pub. Date: Nov. 21, 2024

(54) DISPLAY MODULE AND DISPLAY APPARATUS

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Zheng BAO, Beijing (CN); Haotian YANG, Beijing (CN); Gong CHEN, Beijing (CN); Mingqiang WANG, Beijing (CN); Tao DING, Beijing (CN); Xiaodong HAO, Beijing (CN); Kang WANG, Beijing (CN); Jiaxiang ZHANG, Beijing (CN); Jiuyuan BAI, Beijing (CN); Kun ZUO, Beijing (CN); Xiaoliang FU, Beijing (CN); Bin ZHANG, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/250,652

(22) PCT Filed: Apr. 26, 2022
(86) PCT No.: PCT/CN2022/089393

§ 371 Date: Apr. 26, 2023

(51) Int. Cl. H10K 59/80; H10K 59/90

(52) U.S. Cl. CPC H10K 59/873; H10K 59/8792; H10K 59/90

(57) ABSTRACT

A display module includes a display panel having a fingerprint identification area and a light-transmitting protective film located on a back surface of the display panel. The light-transmitting protective film includes a protective layer, a light-shielding pattern located on a side of the protective layer, and a light-transmitting adhesive layer located on a side of the light-shielding pattern away from the protective layer. The protective layer has a target area. At least the target area is a light-transmitting area, and the target area at least partially overlaps with the fingerprint identification area. The light-shielding pattern defines a plurality of imaging apertures, the plurality of imaging apertures are arranged at intervals, and orthogonal projection of the plurality of imaging apertures on the protective layer are at least located in the target area. A surface of the light-transmitting adhesive layer away from the light-shielding pattern is in contact with the display panel.

### CROSS-REFERENCE TO RELATED APPLICATION

This application is a national phase entry under 35 USC 371 of International Patent Application No. PCT/CN2022/089393, filed on Apr. 26, 2022, which is incorporated herein by reference in its entirety.

### TECHNICAL FIELD

The present disclosure relates to the field of display technologies, and in particular, to a display module and a display apparatus.

### BACKGROUND

At present, a display apparatus has a fingerprint identification function. A fingerprint identification principle is as follows: using the different energy intensities of absorption and reflection of light by peaks and valleys of fingerprints, the fingerprint sensor senses energy differences to produce bright and dark fringes with different brightness for identify fingerprints.

### SUMMARY

In an aspect, a display module is provided. The display module includes a display panel and a light-transmitting protective film. The display panel has a display surface and a back surface opposite to the display surface, and has a fingerprint identification area. The light-transmitting protective film is located on the back surface of the display panel. The light-transmitting protective film includes a protective layer, a light-shielding pattern and a light-transmitting adhesive layer. The protective layer has a target area. At least the target area is a light-transmitting area, and the target area at least partially overlaps with the fingerprint identification area. The light-shielding pattern is located on a side of the protective layer. The light-shielding pattern defines a plurality of imaging apertures, the plurality of imaging apertures are disposed at intervals, and orthogonal projections of the plurality of imaging apertures on the protective layer are at least located in the target area. The light-transmitting adhesive layer is located on a side of the light-shielding pattern away from the protective layer. A surface of the light-transmitting adhesive layer away from the light-shielding pattern is in contact with the display panel.

In some embodiments, an outer contour of an area of the orthogonal projections of the plurality of imaging apertures on the protective layer substantially coincides with an edge of the target area.

In some embodiments, the light-transmitting adhesive layer covers the light-shielding pattern and the protective layer, and the light-transmitting adhesive layer fills the imaging apertures.

In some embodiments, the imaging apertures are each a circular aperture, and an aperture size of an imaging aperture is in a range of 100 μm to 250 μm, inclusive.

In some embodiments, a distance between two adjacent imaging apertures is in a range of 200 μm to 350 μm, inclusive.

In some embodiments, a dimension of the light-shielding pattern in a direction perpendicular to the protective layer is in a range of 200 nm to 500 nm, inclusive.

In some embodiments, a dimension of the protective layer in a direction perpendicular to the protective layer is larger than a dimension of the light-transmitting adhesive layer in the direction perpendicular to the protective layer.

In some embodiments, a ratio of a dimension of the light-transmitting adhesive layer in a direction perpendicular to the protective layer to a dimension of the protective layer in the direction perpendicular to the protective layer is 1:10 to 3:10.

In some embodiments, the display module further includes a heat dissipation film. The heat dissipation film includes a light-shielding material. The heat dissipation film is located on a side of the light-transmitting protective film away from the display panel, and the heat dissipation film is provided with a light-transmitting opening therein. A contour of an orthogonal projection of the light-transmitting opening on the protective layer of the light-transmitting protective film surrounds an area of the orthogonal projections of the plurality of imaging apertures of the light-transmitting protective film on the protective layer.

In some embodiments, the target area of the protective layer substantially coincides with the fingerprint identification area of the display panel.

In some embodiments, a light transmittance of an area of the protective layer other than the target area is smaller than a light transmittance of the target area.

In some embodiments, the surface of the light-transmitting adhesive layer away from the light-shielding pattern is a plane.

In some embodiments, the light-transmitting adhesive layer is made of a material with adhesivity. A surface of the light-transmitting adhesive layer proximate to the protective layer and the light-shielding pattern is bonded to the protective layer and the light-shielding pattern; and the surface of the light-transmitting adhesive layer away from the light-shielding pattern and the protective layer is bonded to the display panel.

In some embodiments, a dimension of the protective layer in a direction perpendicular to the protective layer is in a range of 50 μm to 100 μm, inclusive.

In some embodiments, a dimension of the light-transmitting adhesive layer in a direction perpendicular to the protective layer is in a range of 10 μm to 15 μm, inclusive.

In some embodiments, the heat dissipation film includes an adhesive layer, a buffer layer and a heat dissipation layer that are stacked in sequence in a direction away from the back surface of the display panel.

In another aspect, a display apparatus is provided. The display apparatus includes a display module and a fingerprint sensor. The display module is the display module as described in any of the above embodiments. The fingerprint sensor is located on a side of the light-transmitting protective film of the display module away from the display panel. An orthogonal projection of the fingerprint sensor on the display panel of the display module is at least located in the fingerprint identification area of the display panel.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display apparatus, in accordance with some embodiments;

FIG. 2 is a structural diagram of another display apparatus, in accordance with some embodiments;

FIG. 3 is a structural diagram of a display panel, in accordance with some embodiments;

FIG. 4 is a structural diagram of a light-transmitting protective film in a display module, in accordance with some embodiments;

FIG. 5 is a diagram showing a projection position of a light-shielding metal on a protective layer in a display module, in accordance with some embodiments;

FIG. 6 is a structural diagram of a light-shielding metal in a display module, in accordance with some embodiments;

FIG. 7 is a diagram showing a projection position of another light-shielding metal on a protective layer in a display module, in accordance with some embodiments;

FIG. 8 is a structural diagram of a light-transmitting protective film in a display module before the light-transmitting protective film is connected to a display panel, in accordance with some embodiments;

FIG. 9 is a structural diagram of a display module, in accordance with some embodiments;

FIG. 10 is a flow diagram of a method for manufacturing a light-transmitting protective film, in accordance with some embodiments;

FIGS. 11A to 11F are structural diagrams at different stages of the method for manufacturing a light-transmitting protective film, in accordance with some embodiments;

FIG. 12 is a flow diagram of another method for manufacturing a light-transmitting protective film, in accordance with some embodiments;

FIG. 13 is a flow diagram of a method for manufacturing a display module, in accordance with some embodiments; and

FIG. 14 is a structural diagram of a heat dissipation film, in accordance with some embodiments.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, term “a plurality of” or “the plurality of” means two or more unless otherwise specified.

In the description of some embodiments, the expressions “coupled” and “connected” and derivatives thereof may be used. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is optionally construed as “when” or “in a case where” or “in response to determining that” or “in response to detecting”, depending on the context. Similarly, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”, depending on the context.

The phrase “applicable to” or “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

Exemplary embodiments are described herein with reference to sectional views and/or plan views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

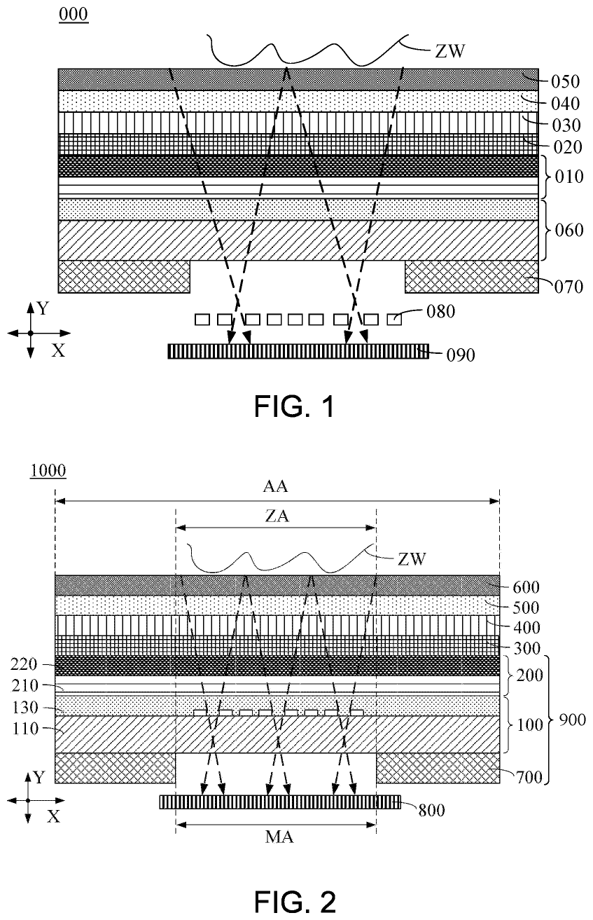

In the related art, as shown in FIG. 1, an organic light-emitting diode (OLED) display apparatus 000 includes a display panel 010, and a touch function layer 020, a polarizer 030, an optically clear adhesive 040 and a protective cover plate 050 that are located on a display side of the display panel 010 and stacked in sequence in a direction away from the display panel 010, and a light-transmitting protective film 060, a heat dissipation layer 070, an optical imaging layer 080 and a fingerprint sensor 090 that are located on a back side of the display panel 010 and stacked in sequence in another direction away from the display panel 010. The optical imaging layer 080 may be a collimator array or a microporous array.

The OLED display apparatus 000 has a fingerprint identification function. As shown in FIG. 1, the fingerprint identification principle of the OLED display apparatus 000 is as follows: light emitted by the display panel 010 is incident on the fingerprint ZW of the human hand to form reflected light (indicated by dotted arrows in the figure), and the reflected light passes through gaps between the sub-pixels in the display panel 010 to be incident on the collimator array or the microporous array on the side of the display panel 010 away from the protective cover plate 050, so that the reflected light is imaged on the fingerprint sensor 090, and the fingerprint sensor 090 obtains fingerprint information based on the formed image, so as to realize the identification of the fingerprint.

However, the collimator array or the microporous array will cause a relatively large thick of the display apparatus 000 in a second direction Y.

In light of this, some embodiments of the present disclosure provide a display module and a display apparatus. The following will be introduced, respectively.

As shown in FIG. 2, some embodiments of the present disclosure provide the display apparatus 1000. The display apparatus 1000 may be any apparatus that displays images whether in motion (e.g., a video) or stationary (e.g., a still image), and regardless of text or image. More specifically, it is expected that the described embodiments may be implemented in or associated with a variety of electronic devices. The variety of electronic devices may include (but are not limit to), for example, mobile telephones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat panel displays, computer monitors, car displays (such as odometer displays), navigators, cockpit controllers and/or displays, camera view displays (such as rear view camera displays in vehicles), electronic photos, electronic billboards or signs, projectors, architectural structures, packaging and aesthetic structures (such as displays for displaying an image of a piece of jewelry), etc.

The display apparatus 1000 includes a frame, and a display panel 200, a circuit board, a display driver integrated circuit (IC) and other electronic components that are disposed in the frame.

The display panel 200 may be an organic light-emitting diode (OLED) display panel, a quantum dot light-emitting diode (QLED) display panel, or a micro light-emitting diode (micro LED) display panel, which is not specifically limited in the present disclosure.

The following embodiments of the present disclosure are all described by considering an example in which the display panel 200 is the OLED display panel, but it should not be considered as being limited to OLED display panel.

In some embodiments, as shown in FIG. 2, the main structure of the display apparatus 1000 includes the display panel 200, a touch function layer 300, an anti-reflection structure such as a polarizer 400, an optically clear adhesive (OCA) layer 500 and a cover plate 600 that are arranged in sequence. In some embodiments, the anti-reflection structure may include color filters and a black matrix.

The display panel 200 includes a base substrate 210 and a light-emitting functional layer 220 located on the base substrate 210. In some embodiments, the display substrate 200 may further include an encapsulation layer (not shown in the figure) for encapsulating the light-emitting functional layer 220. Here, the encapsulation layer may be an encapsulation film or an encapsulation substrate.

The material of the base substrate 210 may be, for example, polyethylene terephthalate (PET), polyimide (PI), cyclo olefin polymer (COP), or the like.

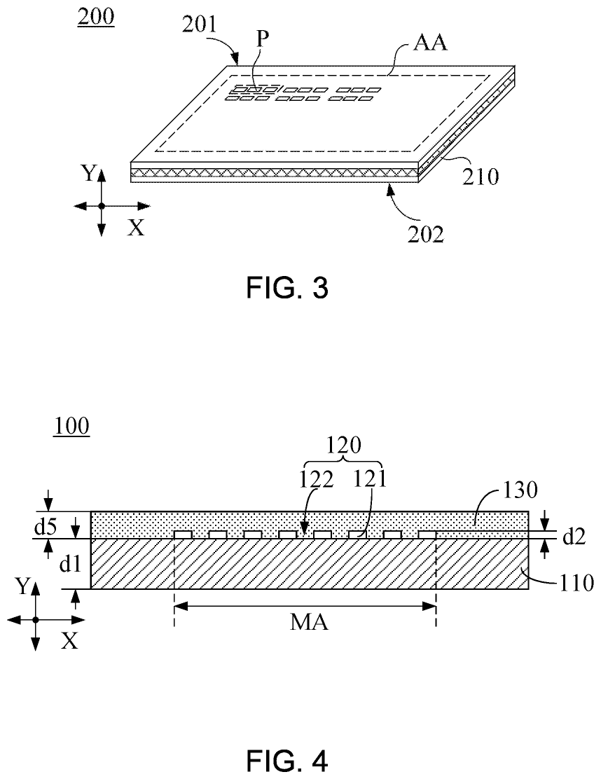

As shown in FIG. 3, the display panel 200 includes a display area (also referred to as an active area, or an active display area) AA and a peripheral area surrounding the display area AA.

The display panel 200 includes sub-pixels P of a plurality of colors in the display area AA. The sub-pixels P of the plurality of colors include at least a sub-pixel of a first color, a sub-pixel of a second color and a sub-pixel of a third color, and the first color, the second color and the third color may be three primary colors (e.g., red, green and blue).

For convenience of description, the sub-pixels P in the embodiments of the present disclosure are described in an example of a matrix arrangement. In this case, sub-pixels P arranged in a line along a first direction X are referred to as sub-pixels P in a same row, and sub-pixels P arranged in a line along the second direction Y are referred to as sub-pixels P in a same column.

Each sub-pixel P includes a light-emitting device and a driving circuit that are disposed on the base substrate 210. The driving circuit includes a plurality of thin film transistors. The light-emitting device includes an anode, a light-emitting layer and a cathode, and the anode is electrically connected to a drain of a thin film transistor, as a driving transistor, among the plurality of thin film transistors in the driving circuit.

In some embodiments, in a case where the anode is electrically connected to the drain of the thin film transistor, as the driving transistor, among the plurality of thin film transistors in the driving circuit, the anode is electrically connected to the drain of the thin film transistor through a transfer electrode, and the transfer electrode is located between a film layer where the drain is located and a film layer where the anode is located.

In a case where the display apparatus 1000 is an electroluminescence display apparatus, the display apparatus 1000 may be a top emission display apparatus. In this case, the anode proximate to the base substrate 210 is opaque, and the cathode far away from the base substrate 210 is transparent or translucent. Alternatively, the display apparatus 1000 may be a bottom emission display apparatus. In this case, the anode proximate to the base substrate 210 is transparent or translucent, and the cathode far away from the base substrate 210 is opaque.

In some embodiments, as shown in FIG. 2, the touch function layer 300 is directly disposed on the display panel 200. In this way, the display panel 200 may be regarded as a base substrate of the touch function layer 300. This structure is beneficial to realizing the thinning of the display apparatus 1000.

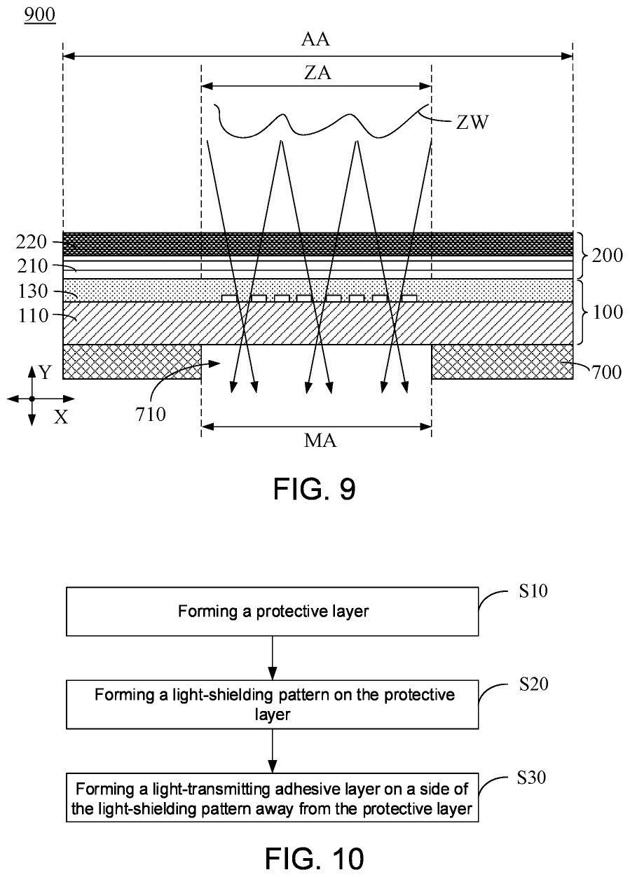

Based on this, in combination with FIGS. 2 and 9, some embodiments of the present disclosure provide a display module 900. The display module 900 includes a display panel 200 and a light-transmitting protective film 100.

The display panel 200 has a fingerprint identification area ZA, and the fingerprint identification area ZA is configured to collect fingerprint information of a user. The fingerprint information may be a fingerprint image, or may also be optical information or electrical information capable of reflecting a fingerprint feature, which is not limited here. It will be understood that when the user's finger is placed in the fingerprint identification area ZA, the display module 900 may collect the fingerprint information of the user.

The fingerprint identification area ZA is located in at least part of the display area AA. As shown in FIG. 9, in some examples, the fingerprint identification area ZA is a partial display area AA, that is, the fingerprint information of the user can be collected only in a specific display area AA. In some other examples, the fingerprint identification area ZA is the display area AA, that is, the fingerprint information of the user can be collected in the entire display area AA.

In a case where the fingerprint identification area ZA is the partial display area AA, the fingerprint identification area ZA may be located in the center or in the border of the display area AA. The outer contour of the fingerprint identification area ZA may be in a shape of a rectangle, a circle, an ellipse, a regular polygon, or the like, which is not limited here.

As shown in FIGS. 2 and 3, the light-transmitting protective film 100 is located on a back surface 202 of the display panel 200, and the back surface 202 of the display panel 200 is a surface opposite to a display surface 201 of the display panel 200. For example, the display surface of the display panel 200 is a surface proximate to the cover plate 600, and the back surface of the display panel 200 is a surface away from the cover plate 600.

As shown in FIG. 4, the light-transmitting protective film 100 includes a protective layer 110, a light-shielding pattern 120 and a light-transmitting adhesive layer 130. The light-shielding pattern 120 is located between the protective layer 110 and the light-transmitting adhesive layer 130, and the light-transmitting adhesive layer 130 is located between the light-shielding pattern 120 and the display panel 200.

The protective layer 110 is located at least in the display area AA. In some examples, a portion of the protective layer 110 may be located in the display area A, and the other portion of the protective layer 110 may be located in the peripheral area. In some other embodiments, the protective layer 110 coincides with the display area AA. In some other embodiments, the protective layer 110 is only located in a part of the display area AA.

The material of the protective layer 110 may include PET, or other suitable materials, which is not limited here.

A dimension d1 of the protective layer 110 in the second direction Y may be in a range of 50 μm to 100 μm, such as 50 μm, 62 μm, 73.4 μm, 88 μm, 95.5 μm or 100 μm. In a case where the dimension d1 of the protective layer 110 in the second direction Y is greater than 100 μm, the amount of light passing through a target area of the protective layer 110 will be reduced, which is not conducive to the imaging effect of the display module 900. In a case where the dimension d1 of the protective layer 110 in the second direction Y is less than 50 μm, the light transmittance of an area other than the target area MA is relatively high, which will increase the amount of light passing through the area of the protective layer 110 other than the target area MA, and is easy to interfere with imaging. Therefore, the dimension d1 of the protective layer 110 in the second direction Y is in the range of 50 μm to 100 μm, which may improve the imaging effect of the display module 900.

The protective layer 110 includes the target area MA. The target area MA at least partially overlaps with the fingerprint identification area ZA. For example, the target area MA substantially overlaps with the fingerprint identification area ZA. The target area MA may be a partial area of the protective layer 110. The target area MA is a light-transmitting area, and the light transmittance of the target area MA may be greater than 90%.

In some examples, a whole of the protective layer 110 may be a light-transmitting area, that is, the target area MA and the area other than the target area MA are each the light-transmitting area.

In some other examples, the target area MA is a light-transmitting area, and the light transmittance of the area of the protective layer 110 other than the target area MA is smaller than the light transmittance of the target area MA. For example, the light transmittance of the area other than the target area MA may be less than 60%, or even less than 30%, which is not limited here.

The light-shielding pattern 120 is located between the protective layer 110 and the display panel 200, and the light-shielding pattern 120 may be in direct contact with the protective layer 110.

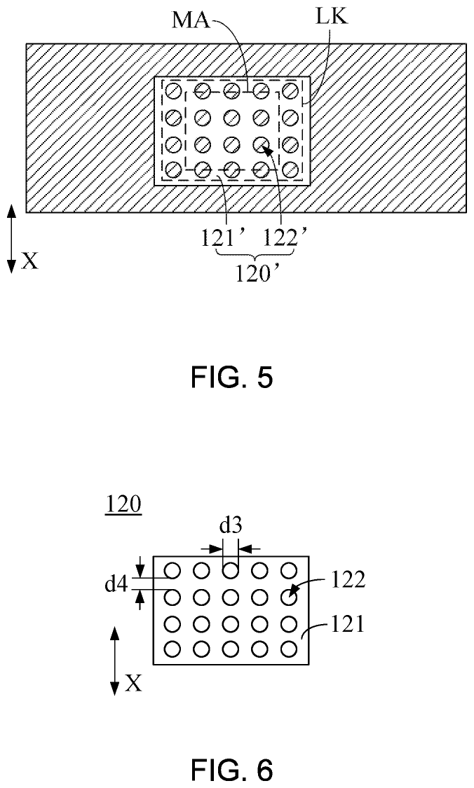

The light-shielding pattern 120 is located at least partially in the target area MA. It can be understood as that an orthogonal projection of the light-shielding pattern 120 on the protective layer 110 is located at least partially in the target area MA. As shown in FIG. 5, in some examples, an orthogonal projection 120′ of a part of the light-shielding pattern is located in the target area MA, and an orthogonal projection 120′ of another part of the light-shielding pattern is located outside the target area MA. In some other examples, the orthogonal projection 120′ of the light-shielding pattern is completely located in the target area MA.

The material of the light-shielding pattern 120 may include a metal material, such as molybdenum (Mo) or aluminum (Al). Alternatively, the material of the light-shielding pattern 120 may include other light-shielding organic or inorganic materials, such as resin.

As shown in FIG. 4, a dimension d2 of the light-shielding pattern 120 in the second direction Y may be in a range of 200 nm to 500 nm, such as 200 nm, 240 nm, 276 nm, 312 nm, 387.3 nm, 400 nm, 444 nm, 479 nm or 500 nm. The dimension d2 of the light-shielding pattern 120 in the second direction Y is greater than 500 nm, which easily increases a step difference of a side of the light-transmitting adhesive layer 130 away from the protective layer 110 and reduces the firmness of bonding between the light-transmitting protective film 100 and the display panel 200. The dimension d2 of the light-shielding pattern 120 in the second direction Y is less than 200 nm, which easily reduces the light-shielding performance of the light-shielding pattern 120 and reduces the imaging effect of the imaging apertures 122. Therefore, the dimension d2 of the light-shielding pattern 120 in the second direction Y is in the range of 200 nm and 500 nm, which may improve firmness of the bonding between the light-transmitting protective film 100 and the display panel 200 and improve the imaging effect of the display module 900.

As shown in FIG. 6, the light-shielding pattern 120 includes a light-shielding portion 121 and imaging apertures 122 provided in the light-shielding portion 121. There may be a plurality of imaging apertures 122. An imaging aperture 122 is configured to allow part of the light emitted by the display panel 200 to pass through, so as to generate an inverted image corresponding to the passed light on a side of the light-shielding pattern 120 away from the display panel 200. In this way, the plurality of imaging apertures 122 cooperate to generate a complete inverted image of the fingerprint on the side of the light-shielding pattern 120 away from the display panel 200.

The imaging aperture 122 may be a circular aperture, an elliptical aperture, a rectangular aperture, a regular polygonal aperture, a rhombus aperture, or the like, which is not limited here. It should be understood that any aperture that may realize the pinhole imaging principle belongs to the imaging aperture 122 in the embodiments of the present disclosure.

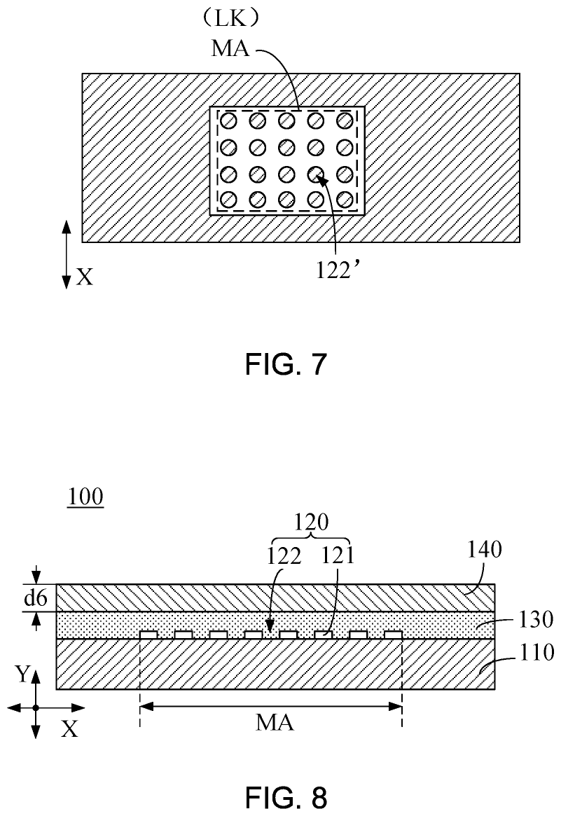

As shown in FIGS. 5 and 7, the orthogonal projection 120′ of the light-shielding pattern 120 on the protective layer 110 includes orthogonal projections 122′ of the imaging apertures 122 on the protective layer 110 and an orthogonal projection 121′ of the light-shielding portion 121 on the protective layer 110. The orthogonal projections 122′ of the imaging apertures 122 on the protective layer 110 are located at least in the target area MA. In some examples, as shown in FIG. 7, all of the orthogonal projections 122′ of the imaging apertures 122 on the protective layer 110 are located in the target area MA. In some other embodiments, as shown in FIG. 5, part of the orthogonal projections 122′ of the imaging apertures 122 on the protective layer 110 are located in the target area MA. For example, for an orthogonal projection 122′ of an imaging aperture 122 at the border on the protective layer 110, a part of the orthogonal projection is located in the target area MA, and the other part of the orthogonal projection is located outside the target area MA.

As shown in FIG. 6, in some embodiments, the imaging aperture 122 is a circular aperture, and the aperture size d3 of the imaging aperture 122 is in a range of 100 μm to 250 μm, such as 100 μm, 128 μm, 167 μm, 203 μm, 222.2 μm, 242 μm or 250 μm. In a case where the aperture size d3 of the imaging aperture 122 is greater than 250 μm, there is a relatively large amount of interference light passing through the imaging aperture 122, which may cause the inverted image of the fingerprint generated on the other side of the light-shielding pattern 120 to be unclear and reduce the imaging effect. In a case where the aperture size d3 of the imaging aperture 122 is less than 100 μm, there is a small amount of light passing through the imaging aperture 122, and the light is likely to cause the interference of the diffraction effect, resulting in reducing the imaging effect. Therefore, the aperture size d3 of the imaging aperture 122 is in the range of 100 μm to 250 μm, which may improve the imaging effect of the display module 900.

It will be noted that the plurality of imaging apertures 122 may have the same aperture size, or the plurality of imaging apertures 122 may have different aperture sizes.

For example, the aperture sizes of the plurality of imaging apertures 122 are all 200 μm. For another example, aperture sizes of some imaging apertures 122 are 150 μm, and aperture sizes of other imaging apertures 122 are 200 μm.

As shown in FIG. 6, the plurality of imaging apertures 122 may be arranged at intervals one other. In some embodiments, a distance d4 between two adjacent imaging apertures 122 is in a range of 200 μm to 350 μm, such as 200 μm, 228 μm, 267 μm, 303 μm, 322.2 μm, 342 μm or 350 μm. In a case where the distance d4 between two adjacent imaging apertures 122 is greater than 350 μm, the inverted images generated by the plurality of imaging apertures 122 are likely to be spliced incompletely, so that a complete inverted image of the fingerprint cannot be obtained. In a case where the distance d4 between two adjacent imaging apertures 122 is less than 200 μm, the overlapping degree of the inverted images generated by the plurality of imaging apertures 122 is relatively high, and the light utilization efficiency is relatively low. Therefore, the distance d4 between two adjacent imaging apertures 122 is in the range of 200 μm and 350 μm, which may obtain a complete inverted image of the fingerprint and improve the light utilization rate.

It will be noted that, the imaging apertures 122 of the light-shielding pattern 120 may have the same distance therebetween, or different imaging apertures 122 may have different distances therebetween. For example, the distances each between two adjacent imaging apertures 122 in the plurality of imaging apertures 122 are all 250 μm. For another example, distances each between two adjacent imaging apertures 122 in some imaging apertures 122 are 280 μm, and distances each between two adjacent imaging apertures 122 in other imaging apertures 122 are 320 μm.

As shown in FIG. 4, the light-transmitting adhesive layer 130 may be located on a side of the light-shielding pattern 120 away from the protective layer 110 and cover the light-shielding pattern 120. A surface of the light-transmitting adhesive layer 130 away from the light-shielding pattern 120 is in contact with the display panel 200. In some examples, the light-transmitting adhesive layer 130 also covers the protective layer 110. The surface of the light-transmitting adhesive layer 130 away from the protective layer 110 may be a plane, a curved surface or a rough surface, which is not limited here.

The material of the light-transmitting adhesive layer 130 may include an organic material, or other suitable materials. In some examples, the light-transmitting adhesive layer 130 may be a pressure sensitive adhesive (PSA). The light transmittance of the light-transmitting adhesive layer 130 may be greater than 90%.

As shown in FIG. 4, in some embodiments, the surface of the light-transmitting adhesive layer 130 away from the light-shielding pattern 120 and the protective layer 110 is an adhesive surface, and the adhesive surface is the plane.

The light-transmitting adhesive layer 130 may be made of a material with adhesivity. A surface of the light-transmitting adhesive layer 130 proximate to the protective layer 110 and the light-shielding pattern 120 is bonded to the protective layer 110 and the light-shielding pattern 120. The surface of the light-transmitting adhesive layer 130 away from the light-shielding pattern 120 and the protective layer 110 may be configured to be bonded to the display panel 200.

The back surface of the display panel 200 is a plane, and the surface of the light-transmitting adhesive layer 130 away from the light-shielding pattern 120 and the protective layer 110 is the plane. Therefore, the light-transmitting adhesive layer 130 may be well bonded to the display panel 200, so as to improve the strength of the connection between the light-transmitting protective film 100 and the display panel 200.

A dimension d5 of the light-transmitting adhesive layer 130 in the second direction Y may be in a range of 10 μm to 15 μm, such as 10 μm, 11.4 μm, 12.4 μm, 13.5 μm, 14.6 μm or 15 μm. In a case where the dimension d5 of the light-transmitting adhesive layer 130 in the second direction Y is greater than 15 μm, the light transmittance of the light-transmitting adhesive layer 130 may be reduced, which is not conducive to the imaging effect of the display module 900. In a case where the dimension d5 of the light-transmitting adhesive layer 130 in the second direction Y is less than 10 μm, a step difference is likely to appear at the position covering the light-shielding pattern 120, which may reduce the firmness of the bonding between the light-transmitting adhesive layer 130 and the display panel 200. Therefore, the dimension d5 of the light-transmitting adhesive layer 130 in the second direction Y is in the range of 10 μm to 15 μm, which may balance the firmness of the bonding between the light-transmitting adhesive layer 130 and the display panel 200 and the imaging effect of the display module 900.

In some embodiments, the dimension d5 of the light-transmitting adhesive layer 130 in the second direction Y may be 15 μm, and the dimension d1 of the protective layer 110 in the second direction Y may be 50 μm. That is, a ratio of the dimension of the light-transmitting adhesive layer 130 in the second direction Y to the dimension of the protective layer 110 in the second direction Y may be 3:10.

In some other embodiments, the dimension d5 of the light-transmitting adhesive layer 130 in the second direction Y may be 10 μm, and the dimension d1 of the protective layer 110 in the second direction Y may be 100 μm. That is, the ratio of the dimension of the light-transmitting adhesive layer 130 in the second direction Y to the dimension of the protective layer 110 in the second direction Y may be 1:10.

In summary, in combination with the case that the dimension d1 of the protective layer 110 in the second direction Y may be in the range of 50 μm to 100 μm, and the dimension d5 of the light-transmitting adhesive layer 130 in the second direction Y may be in the range of 10 μm to 15 μm, the ratio between the dimension d5 of the light-transmitting adhesive layer 130 in the second direction Y and the dimension d1 of the protective layer 110 in the second direction Y may be in the range of 1:10 to 3:10.

The order in which the light radiating from the display panel 200 to the light-transmitting protective film 100 passes through the light-transmitting protective film 100 is as follows: firstly passing through the light-transmitting adhesive layer 130, then passing through the imaging apertures 122, and finally passing through the target area MA of the protective layer 110. As a result, the inverted image of the fingerprint is produced on the side of the light-transmitting protective film 100 away from the display panel 200.

In the display module 900 provided by the embodiment of the present disclosure, since the imaging apertures 122 are provided inside the light-transmitting protective film 100, the thickness (the dimension in the second direction Y) of the light-transmitting protective film 100 will not increase, and the imaging of the fingerprint may also be realized. Compared with the structure in FIG. 1 in the related art, the space for additional providing the microporous array or the collimator array may be saved in the second direction Y, thereby achieving the effect of thinning the display module 900 and facilitating the light and thin design for the display apparatus 1000.

As shown in FIG. 7, in some embodiments, an outer contour LK of an area of the orthogonal projections of the plurality of imaging apertures 122 on the protective layer 110 approximately coincides with an edge of the target area MA.

The area of the orthogonal projections of the plurality of imaging apertures 122 on the protective layer 110 refers to an area surrounding the orthogonal projections 122′ of all the imaging apertures 122 on the protective layer 110, that is, the area surrounding the orthogonal projections 122′ of the plurality of imaging apertures 122 on the protective layer 110.

The outer contour LK of the area of the orthogonal projections of the plurality of imaging apertures 122 on the protective layer 110 approximately coincides with the edge of the target area MA, which may be understood that the plurality of imaging apertures 122 of the light-shielding pattern 120 are all located in the target area MA.

In some examples, the orthogonal projection of the light-shielding pattern 120 on the protective layer 110 may exceed the target area MA, while the plurality of imaging apertures 122 of the light-shielding pattern 120 are located in the target area MA.

In some other embodiments, as shown in FIG. 5, the outer contour LK of the area of the orthogonal projections of the plurality of imaging apertures 122 on the protective layer 110 surrounds the edge of the target area MA.

That is, a part of the area of the orthogonal projections of the plurality of imaging apertures 122 on the protective layer 110 covers the target area MA, and another part thereof is located outside the edge of the target area MA. In this way, in a case where there is a slight error of the position between the light-shielding pattern 120 and the protective layer 110, it may also be ensured that the orthogonal projection of the light-shielding pattern 120 on the protective layer 110 is located in the target area MA.

This embodiment may allow the slight error of the position between the light-shielding pattern 120 and the protective layer 110 in the actual manufacturing process, thereby improving the yield of the light-transmitting protective film 100.

As shown in FIG. 4, in some embodiments, the light-transmitting adhesive layer 130 covers the light-shielding pattern 120 and the protective layer 110, and the light-transmitting adhesive layer 130 fills the imaging apertures 122.

In this embodiment, the imaging apertures 122 are filled with part of the light-transmitting adhesive layer 130. Since the light-transmitting adhesive layer 130 itself has a relatively high light transmittance, the light-transmitting adhesive layer 130 will not affect the imaging effect of the imaging apertures 122.

In addition, compared with that the light passes through the light-transmitting protective film 100 through the light-transmitting adhesive layer 130, air and the protective layer 110, the light passes through the light-transmitting protective film 100 through the light-transmitting adhesive layer 130 and the protective layer 110 in this embodiment, which may reduce the transmission media of light, thereby reducing the amount of light transmission lost due to total reflection between two media, and improving the imaging efficiency of the inverted image of the fingerprint.

In some embodiments, as shown in FIG. 9, the display module 900 further includes a heat dissipation film 700. The heat dissipation film 700 includes a light-shielding material. The heat dissipation film 700 may be a super clean foam (SCF) layer. The heat dissipation film 700 may be of a single-layer structure, or a composite layer structure, which has the functions of shading and heat dissipation.

In some examples, as shown in FIG. 14, the heat dissipation film 700 includes an adhesive layer 701, a buffer layer 702 and a heat dissipation layer 703 that are stacked in sequence in a direction away from the back surface of the display panel 200. The adhesive layer may include reticulate adhesive, or other suitable materials. The heat dissipation layer may include a thermally conductive metal material, such as copper (Cu); alternatively, the heat dissipation layer may include a graphene material, or other suitable materials. The buffer layer may include a foam material, or other suitable materials.

The heat dissipation film 700 may be bonded to the back surface of the protective layer 110 of the light-transmitting protective film 100, so as to realize the connection with the light-transmitting protective film 100. For example, the adhesive layer of the heat dissipation film 700 is bonded to the back surface of the protective layer 110 of the light-transmitting protective film 100.

The heat dissipation film 700 is located on a side of the light-transmitting protective film 100 away from the display panel 200, and the heat dissipation film 700 is provided with a light-transmitting opening 710 therein. A contour of an orthogonal projection of the light-transmitting opening 710 on the protective layer 110 of the light-transmitting protective film 100 surrounds the area of the orthogonal projections of the plurality of imaging apertures 122 of the light-transmitting protective film 100 on the protective layer 110.

In some examples, the contour of the orthogonal projection of the light-transmitting opening 710 on the protective layer 110 of the light-transmitting protective film 100 may approximately coincide with the edge of the area of the orthogonal projections of the plurality of imaging apertures 122 of the light-transmitting protective film 100 on the protective layer 110.

The light-transmitting opening 710 may allow the reflected light passing through the imaging aperture 122 to pass through, and may block the light outside the target area MA, so as to prevent the light outside the target area MA from interfering with imaging, thereby improving the reliability of imaging.

In some other examples, the contour of the orthogonal projection of the light-transmitting opening 710 on the protective layer 110 of the light-transmitting protective film 100 may cover the area of the orthogonal projections of the plurality of imaging apertures 122 of the light-transmitting protective film 100 on the protective layer 110, and a peripheral area of this area of the orthogonal projections. In this way, the alignment error between the light-transmitting opening 710 and the target area MA may be overcome to a certain extent in actual production, and the yield of manufacturing the display module 900 may be improved.

In summary, the light exiting from the display panel 200 is reflected by the fingerprint in the fingerprint identification area ZA, and the reflected light can pass through the gaps between the sub-pixels P in the display panel 200, and then pass through the light-transmitting adhesive layer 130, the imaging apertures 122, the target area MA of the protective layer 110, and the light-transmitting opening of the heat dissipation film 700 in sequence, so as to generate an inverted image of the fingerprint on the back surface of the display module 900.

The target area MA of the protective layer 110 of the light-transmitting protective film 100 substantially coincides with the fingerprint identification area ZA of the display panel 200. In this way, a relatively large amount of light in the fingerprint identification area ZA may pass through the target area MA to the back side of the display module 900, thereby improving the integrity of the imaging on the back side of the display module 900.

As shown in FIG. 2, some embodiments of the present disclosure provide a display apparatus 1000. The display apparatus 1000 includes a display module 900 and a fingerprint sensor 800.

The fingerprint sensor 800 is located on a side of the light-transmitting protective film 100 of the display module 900 away from the display panel 200. The orthogonal projection of the fingerprint sensor 800 on the display panel 200 of the display module 900 is at least located in the fingerprint identification area ZA of the display panel 200.

An area of the fingerprint sensor 800 is larger than an area of the fingerprint identification area ZA, and the fingerprint sensor 800 is used to receive the reflected light, capable of generating the inverted image of the fingerprint, from the fingerprint identification area ZA and passing through the light-transmitting protective film 100. The fingerprint sensor 800 is configured to obtain fingerprint information based on the reflected light for generating the inverted image of the fingerprint, so as to realize the fingerprint identification function.

As shown in FIG. 2, the display panel 200 in the display apparatus 1000 emits light for displaying. The exiting light passes through the touch function layer 300, the polarizer 400, the OCA layer 500 and the cover plate 600 in sequence to be incident on the surface of the fingerprint, and is reflected by the surface of the fingerprint. The reflected light passes through the cover plate 600, the OCA layer 500, the polarizer 400 and the touch function layer 300 in sequence, and passes through the gaps between the sub-pixels in the display panel 200, the light-transmitting adhesive layer 130, the imaging apertures, the target area MA of the protective layer 100 and the light-transmitting opening of the heat dissipation film 700, so as to generating the inverted image of the fingerprint on the surface of the fingerprint sensor 800.

In some examples, the image sensor 800 is an imaging sensor. The image sensor obtains the fingerprint image based on the inverted image of the fingerprint generated by the reflected light, so as to realize the fingerprint identification function.

It will be noted that, other light-transmitting functional film layer(s) may be included between the fingerprint sensor 800 and the display module 900, or no other functional film layer(s) are included therebetween, which is not limited here.

In the display apparatus 1000, since the imaging apertures 122 are provided inside the light-transmitting protective film 100, the thickness (the dimension in the second direction Y) of the light-transmitting protective film 100 will not increase, and the imaging of the fingerprint may also be realized. Compared with the structure in FIG. 1 in the related art, the space for additional providing the microporous array or the collimator array may be saved in the second direction Y, thereby achieving the effect of thinning the display module 900.

The light-transmitting protective film 100 may be attached to the back surface of the display panel 200 by utilizing the adhesivity of the light-transmitting adhesive layer 130 after being formed. That is, the light-transmitting adhesive layer 130 may be manufactured separately.

Therefore, embodiments of the present disclosure provide a method for manufacturing the light-transmitting protective film. As shown in FIG. 10, the method for manufacturing the light-transmitting protective film includes steps S10 to S30.

In S10, a protective layer 110 is formed. The protective layer 110 has a target area MA, and at least the target area MA is a light-transmitting area.

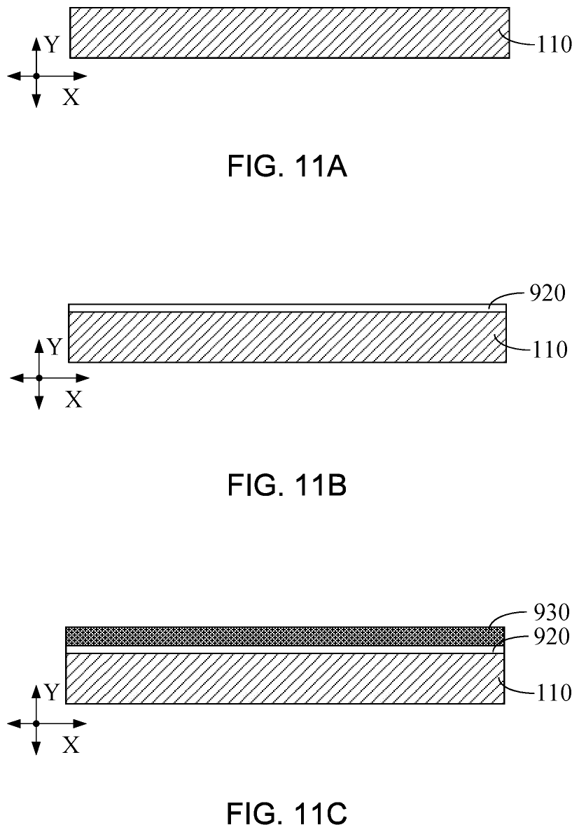

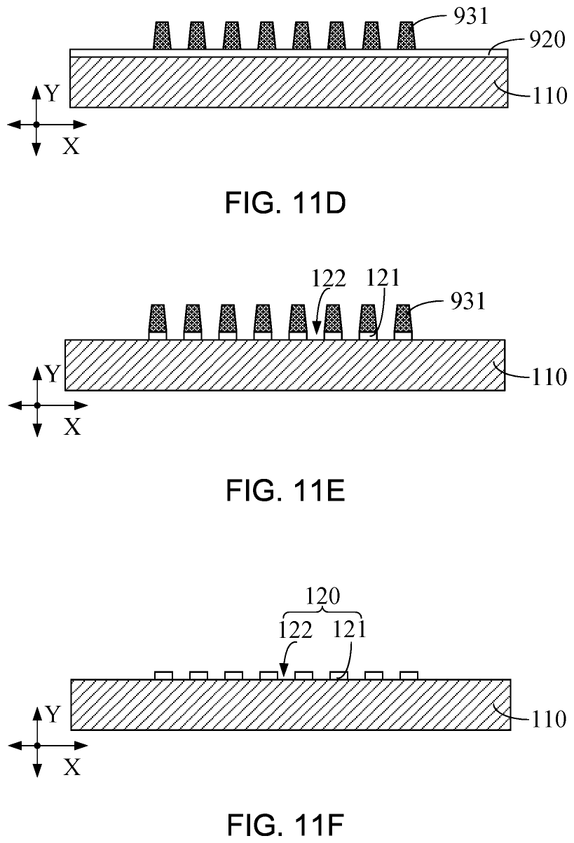

As shown in FIG. 11A, the protective layer 110 may be obtained by sequentially performing crystallization, drying, extrusion molding, cooling shaping, drawing and coiling on the protective material. The size of the protective layer 110 may be determined according to the size of the display apparatus to which the protective layer 110 is applied, and display apparatuses with different sizes may correspond to protective layer 110 with different sizes.

The above-mentioned protective material may be polyethylene terephthalate, or other suitable materials, which is not limited here.

In S20, a light-shielding pattern 120 is formed on the protective layer 110. The light-shielding pattern 120 defines a plurality of imaging apertures 122, the plurality of imaging apertures 122 are spaced apart from one other, and orthogonal projections of the plurality of imaging apertures 122 on the protective layer 110 are at least located in the target area MA.

In some examples, as shown in FIG. 11B, a light-shielding material may be deposited by a deposition process to form a light-shielding material layer 920 on the protective layer 110. The light-shielding material may be a light-shielding metal material, such as molybdenum (Mo) or aluminum (Al); alternatively, the light-shielding material may be other suitable materials, which is not limited here.

In a case where the light-shielding material is molybdenum (Mo) or aluminum (Al), the light-shielding metal material may be deposited by means of magnetron sputtering.

As shown in FIG. 11C, a photoresist layer 930 may be formed by coating on the light-shielding material layer 920. The material of the photoresist layer 930 may include polyimide, or other suitable materials. The photoresist may be a positive photoresist or a negative photoresist, which is not limited here. The following is described in an example of the material of the photoresist layer including the positive photoresist.

As shown in FIG. 11D, the photoresist layer is exposed and developed using a mask to remove part of the photoresist layer 930, so as to remain a photoresist portion 931. Afterwards, as shown in FIG. 11E, part of the light-shielding material layer 920 is removed by an etching process to form imaging apertures 122 and remain a light-shielding portion 121. The etching process may adopt a wet etching process, or a plasma etching process.

As shown in FIG. 11F, the remaining photoresist portion 931 is removed to expose the light-shielding pattern 120 with the imaging apertures 122 and the light-shielding portion 121.

In S30, a light-transmitting adhesive layer 130 is formed on a side of the light-shielding pattern 120 away from the protective layer 110.

A light-transmitting adhesive material is applied by coating on a side of the light-shielding pattern 120 away from the protective layer 110, so as to form a light-transmitting adhesive material layer. The light-transmitting adhesive material layer is dried to form the light-transmitting adhesive layer 130 covering the light-shielding pattern 120.

In some examples, as shown in FIG. 4, the light-transmitting adhesive layer 130 covers a surface of the light-shielding pattern 120 away from the protective layer 110 and a surface of the protective layer 110 proximate to the light-shielding pattern 120.

A surface of the light-transmitting adhesive layer 130 away from the protective layer 110 may be a plane.

In the method for manufacturing the light-transmitting protective film provided by the embodiments of the present disclosure, since the imaging apertures 122 are provided inside the light-transmitting protective film 100, the thickness (the dimension in the second direction Y) of the light-transmitting protective film 100 will not increase, and the imaging of the fingerprint may also be realized. Compared with the structure in FIG. 1 in the related art, the space for additional providing the microporous array or the collimator array may be saved in the second direction Y, thereby achieving the effect of thinning the display module 900.

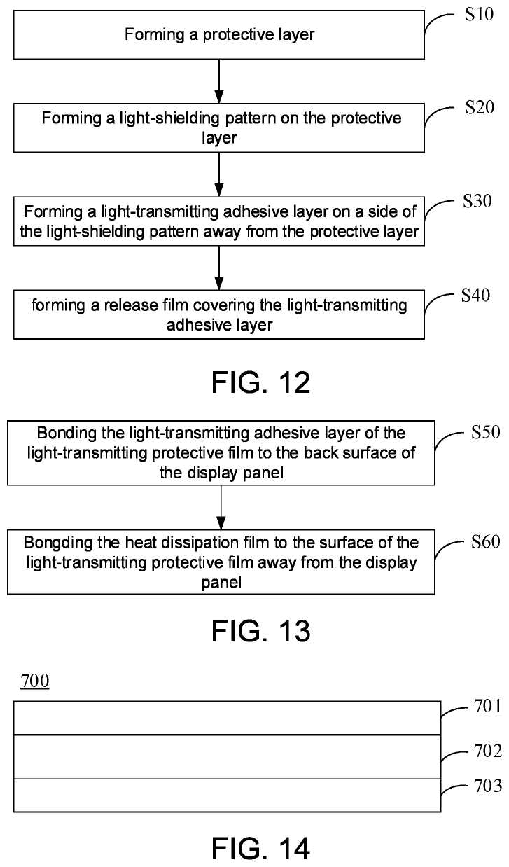

As shown in FIG. 12, in some embodiments, after S30, the method for manufacturing the light-transmitting protective film may further include a step S40: as shown in FIG. 8, forming a release film 140 covering the light-transmitting adhesive layer 130.

As shown in FIG. 8, the release film 140 may protect the light-transmitting adhesive layer 130 while maintaining the adhesivity of the light-transmitting adhesive layer 130, which facilitates storage and transportation of the light-transmitting protective film 100 attached with the release film 140.

Before the light-transmitting adhesive layer 130 is bonded to the display panel 200, the release film 140 covers the surface of the light-transmitting adhesive layer 130 away from the light-shielding pattern 120 and the protective layer 110, so as to protect the light-transmitting adhesive layer 130.

The release film 140 may protect the light-transmitting adhesive layer 130 while maintaining the adhesivity of the light-transmitting adhesive layer 130, which facilitates storage and transportation of the light-transmitting protective film 100 attached with the release film 140. Before the light-transmitting protective film 100 is bonded to the display panel 200, the release film 140 is torn off, so that the light-transmitting adhesive layer 130 is bonded to the back surface of the display panel 200.

A dimension d6 of the release film 140 in the second direction Y may be in a range of 20 μm to 30 μm, such as 20 μm, 22.3 μm, 23.6 μm, 25 μm, 26.8 μm, 28 μm or 30 μm. The dimension d6 of the release film 140 in the second direction Y being greater than 30 μm is likely to cause waste of materials, and the dimension d6 of the release film 140 in the second direction Y being less than 20 μm may lead to an excessively thin release film 140 and a relatively poor protective effect. The dimension d6 of the release film 140 in the second direction Y is in the range of 20 μm and 30 μm, which may balance the protection effect of the light-transmitting adhesive layer 130 and the effect of saving materials.

Embodiments of the present disclosure provide a method for manufacturing a display module. As shown in FIG. 13, the method for manufacturing the display module includes steps S50 and S60.

In S50, the light-transmitting adhesive layer 130 of the light-transmitting protective film 100 is bonded to the back surface of the display panel 200. The target area MA of the light-transmitting protective film 100 at least partially overlaps with the fingerprint identification area of the display panel 200.

After the target area MA of the light-transmitting protective film 100 is aligned with the fingerprint identification area of the display panel 200, the light-transmitting protective film 100 is bonded to the back surface of the base substrate 210 of the display panel 200 by using the adhesivity of the light-transmitting adhesive layer 130.

In a case where the light-transmitting protective film 100 also has the release film 140, before S40, the method further includes removing the release film 140.

In S60, the heat dissipation film 700 is bonded to the surface of the light-transmitting protective film 100 away from the display panel 200. The contour of the orthogonal projection of the light-transmitting opening 710 of the heat dissipation film 700 on the protective layer 110 of the light-transmitting protective film 100 surrounds the area of the orthogonal projections of the plurality of imaging apertures 122 of the light-transmitting protective film 100 on the protective layer 110.

After the target area MA of the light-transmitting protective film 100 is aligned with the light-transmitting opening 710 of the heat dissipation film 700, the heat dissipation film 700 is bonded to the surface of the light-transmitting protective film 100 away from the display panel 200.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display module, comprising:
a display panel having a display surface and a back surface opposite to the display surface, and having a fingerprint identification area; and
a light-transmitting protective film located on the back surface of the display panel; the light-transmitting protective film includes:
a protective layer having a target area, wherein at least the target area is a light-transmitting area, and the target area at least partially overlaps with the fingerprint identification area;
a light-shielding pattern located on a side of the protective layer, wherein the light-shielding pattern defines a plurality of imaging apertures, the plurality of imaging apertures are disposed at intervals, and orthogonal projections of the plurality of imaging apertures on the protective layer are at least located in the target area; and
a light-transmitting adhesive layer located on a side of the light-shielding pattern away from the protective layer, wherein a surface of the light-transmitting adhesive layer away from the light-shielding pattern is in contact with the display panel.

2. The display module according to claim 1, wherein an outer contour of an area of the orthogonal projections of the plurality of imaging apertures on the protective layer substantially coincides with an edge of the target area.

3. The display module according to claim 1, wherein the light-transmitting adhesive layer covers the light-shielding pattern and the protective layer, and the light-transmitting adhesive layer fills the imaging apertures.

4. The display module according to claim 1, wherein the imaging apertures are each a circular aperture, and an aperture size of an imaging aperture is in a range of 100 μm to 250 μm, inclusive.

5. The display module according to claim 1, wherein a distance between two adjacent imaging apertures is in a range of 200 μm to 350 μm, inclusive.

6. The display module according to claim 1, wherein a dimension of the light-shielding pattern in a direction perpendicular to the protective layer is in a range of 200 nm to 500 nm, inclusive.

7. The display module according to claim 1, wherein a dimension of the protective layer in a direction perpendicular to the protective layer is larger than a dimension of the light-transmitting adhesive layer in the direction perpendicular to the protective layer.

8. The display module according to claim 1, wherein a ratio of a dimension of the light-transmitting adhesive layer in a direction perpendicular to the protective layer to a dimension of the protective layer in the direction perpendicular to the protective layer is 1:10 to 3:10.

9. The display module according to claim 1, further comprising:
a heat dissipation film, wherein the heat dissipation film includes a light-shielding material; the heat dissipation film is located on a side of the light-transmitting protective film away from the display panel, and the heat dissipation film is provided with a light-transmitting opening therein, wherein
a contour of an orthogonal projection of the light-transmitting opening on the protective layer of the light-transmitting protective film surrounds an area of the orthogonal projections of the plurality of imaging apertures of the light-transmitting protective film on the protective layer.

10. A display apparatus, comprising:
the display module according to claim 1; and
a fingerprint sensor located on a side of the light-transmitting protective film of the display module away from the display panel, wherein an orthogonal projection of the fingerprint sensor on the display panel of the display module is at least located in the fingerprint identification area of the display panel.

11. The display module according to claim 1, wherein the target area of the protective layer substantially coincides with the fingerprint identification area of the display panel.

12. The display module according to claim 1, wherein a light transmittance of an area of the protective layer other than the target area is smaller than a light transmittance of the target area.

13. The display module according to claim 1, wherein the surface of the light-transmitting adhesive layer away from the light-shielding pattern is a plane.

14. The display module according to claim 1, wherein the light-transmitting adhesive layer is made of a material with adhesivity; a surface of the light-transmitting adhesive layer proximate to the protective layer and the light-shielding pattern is bonded to the protective layer and the light-shielding pattern; and the surface of the light-transmitting adhesive layer away from the light-shielding pattern and the protective layer is bonded to the display panel.

15. The display module according to claim 1, wherein a dimension of the protective layer in a direction perpendicular to the protective layer is in a range of 50 μm to 100 μm, inclusive.

16. The display module according to claim 1, wherein a dimension of the light-transmitting adhesive layer in a direction perpendicular to the protective layer is in a range of 10 μm to 15 μm, inclusive.

17. The display module according to claim 9, wherein the heat dissipation film includes an adhesive layer, a buffer layer and a heat dissipation layer that are stacked in sequence in a direction away from the back surface of the display panel.
